(19) United States
(12) Patent Application Publication
(10) Pub. No.: US 2006/0145245 A1
(43) Pub. Date: Jul. 6, 2006

(54) Field-effect transistor, its manufacturing method, and complementary field-effect transistor

(76) Inventors: Yoshihiro Hara, Osaka (JP); Takeshi Takagi, Kyoto (JP)

Correspondence Address: PANASONIC PATENT CENTER;c/o MCDERMOTT WILL & EMERY LLP, 600 13TH STREET, NW, WASHINGTON, DC, 20005-3096, US

(21) Appl. No.: 10/544,486

(22) PCT Filed: Feb. 9, 2004
(86) PCT No.: PCT/JP04/01321

§ 371 Date: Aug. 4, 2005

(30) Foreign Application Priority Data
Feb. 7, 2003 (JP) 2003-031203

(51) Int. Cl. H01L 29/76

(52) U.S. Cl. 257/327; 257/368

(57) ABSTRACT

A field effect transistor comprises: a semiconductor substrate; a semiconductor layer provided on the semiconductor substrate, the semiconductor layer including a body region which contains an impurity of a first conductivity type; a gate dielectric film provided on the semiconductor layer; a gate electrode provided on the gate dielectric film; and a source region and a drain region provided in the semiconductor layer at positions below the sides of the gate electrode, the source region and the drain region containing an impurity of a second conductivity type. The gate electrode and the body region are electrically short-circuited. In the semiconductor layer except for the source region and the drain region, at least part of a junction portion bordering on the source region or the drain region contains the impurity of the first conductivity type with a higher concentration than in the body region except for junction portions bordering on the source region and the drain region.

### TECHNICAL FIELD

The present invention relates to a field effect transistor wherein a gate electrode and a body region are electrically short-circuited and to a fabrication method thereof.

### BACKGROUND ART

Recently, the LSI fabrication technology has been remarkably advanced. Until now, higher-speed LSIs, lower-voltage devices, and cost reduction have been realized especially due to the advancement of microprocessing technology. Further, along with accelerated proliferation of portable terminals, such as mobile phones, and the like, reduction in power consumption has been more strongly demanded. In order to reduce the power consumption of the LSI, employing a lower voltage, i e., decreasing the power supply voltage, is one of the most effective solutions. To decrease the power supply voltage, it is indispensable to decrease the threshold voltage of field effect transistors of the LSI.

However, in the case of decreasing the threshold voltage using a conventional scaling method, a leak current flowing through a transistor which is in an off state increases as the threshold voltage decreases. To overcome this disadvantage, a Dynamic Threshold MOSFET (DTMOS) has been devised.

The operation principle of this DTMOS is described with reference to FIGS. 18 to 20.

FIG. 18 shows a cross section of a common p-channel DTMOS 500. As shown, the conventional DTMOS 500 includes a p⁻ semiconductor substrate 501, an n-type body region 502 provided over the p⁻ semiconductor substrate 501, a gate oxide film 506 provided on the n-type body region 502, a gate electrode 507 provided on the gate oxide film 506, and a p⁺ source region 508 and a p⁺ drain region 509 provided at the sides of the gate electrode 507. The gate electrode 507 and the body region 502 are electrically short-circuited.

FIG. 19 illustrates the operation characteristic of the conventional p-channel DTMOS. FIG. 20 illustrates a drain current and a body current in the conventional DTMOS. FIGS. 19 and 20 both show the examined characteristics of a p-type DTMOS.

In FIG. 19, thin lines illustrate change of the drain current-gate voltage characteristic of a MOSFET according to the body voltage. It is seen that the drain current greatly changes according to the body voltage, i.e., the substrate bias. This phenomenon is referred to as the substrate bias effect of MOSFET. Now, if the gate electrode 507 and the body region 502 are electrically short-circuited as shown in FIG. 18, the body voltage changes simultaneously with the gate voltage. Therefore, the drain current-gate voltage characteristic of DTMOS is as represented by the thick line of FIG. 19. As a result, the drain current rises steeply with respect to the gate voltage, indicating an ideal value of 60 mV/dec at room temperature. Further, as shown in FIG. 19, as the threshold voltage decreases, the on current increases, and in addition, the off current also decreases. Thus, in the DTMOS, the threshold voltage can be decreased while the ratio between the on current and the off current is maintained high with respect to a MOSFET. Such a conventional DTMOS is disclosed in, for example, F. Assaderaghi et al., “A Dynamic Threshold Voltage MOSFET (DTMOS) for Ultra-Low Voltage Operation,” IEDM Tech. Dig., pp. 809-812, 1994, and H. Kotaki et al., “Novel Low Capacitance Sidewall Elevated Drain Dynamic Threshold Voltage MOSFET (LCSED) for Ultra Low Power Dual Gate CMOS Technology,” IEDM Tech. Dig., pp. 415-418, 1998.

Problems to be Solved

However, the above-described conventional DTMOS has disadvantages as 5 described blow. In the DTMOS, since the gate electrode and the body region are short-circuited, as the gate voltage, i.e., the body voltage, is increased, a voltage of a forward direction is applied to a diode formed by the body region and the source region or a diode formed by the body region and the drain region. Accordingly, the body current, which is a forward direction current of the diode, abruptly flows as shown in FIG. 20, and the power consumption abruptly increases. This is remarkably seen at a junction between the source region whose voltage is fixed to the ground and the body region. As shown in FIG. 20, under a high gate voltage, the body current is nonnegligibly large as compared with the drain current. Therefore, the influence of the body current on the power consumption of the entire DTMOS is nonnegligible. Thus, in the DTMOS, suppression of the body current is a significant challenge. It should be noted that the “high gate voltage” means that the gate voltage has a large absolute value.

Disclosure of Invention

The present invention was conceived for the purpose of overcoming the above-described conventionally-existing problems. An objective of the present invention is to provide a DTMOS capable of suppressing an increase of the body current even under a high gate voltage, thereby realizing a reduction in power consumption.

A field effect transistor of the present invention comprises: a semiconductor substrate; a semiconductor layer provided on the semiconductor substrate, the semiconductor layer including a body region which contains an impurity of a first conductivity type; a gate dielectric film provided on the semiconductor layer; a gate electrode provided on the gate dielectric film; and a source region and a drain region provided in the semiconductor layer at positions below the sides of the gate electrode, the source region and the drain region containing an impurity of a second conductivity type, wherein the gate electrode and the body region are electrically short-circuited, and in the semiconductor layer except for the source region and the drain region, at least part of a junction portion bordering on the source region or the drain region contains the impurity of the first conductivity type with a higher concentration than in the body region except for junction portions bordering on the source region and the drain region.

With the above structure, an energy barrier is provided against an electric current flowing through a pn junction formed by the body region and the source region or drain region and an electric current flowing from a channel layer to the source region. Therefore, the body current is suppressed. Meanwhile, a high impurity concentration region is restricted in a junction portion bordering on the source region or drain region. Thus, the power consumption is reduced while deterioration of the carrier mobility is suppressed.

In the semiconductor layer except for the source region and the drain region, the at least part of the junction portion bordering on the source region contains the impurity of the first conductivity type with a higher concentration than in the body region except for the junction portions bordering on the source region and the drain region. Since the body current is eminently seen between the body region and the source region, the high impurity concentration region is restricted while the body current is effectively suppressed, whereby deterioration of the carrier mobility can be decreased.

In the semiconductor layer except for the source region and the drain region, a junction portion bordering on a side surface of the source region or the drain region contains the impurity of the first conductivity type with a higher concentration than in the body region except for the junction portions bordering on the source region and the drain region. Since the body current flows from the body region, the channel region, or the like, to side surfaces of the source region or drain region in a concentrated manner, the body current can be effectively suppressed with this structure.

The semiconductor layer includes a SiGe layer formed of Si₁₋ₓGeₓ (0<x≦1) on or above the body region. In the SiGe layer, a junction portion bordering on the source region or the drain region contains the impurity of the first conductivity type with a higher concentration than in the body region except for the junction portions bordering on the source region and the drain region. With this structure, the body current can be suppressed more effectively.

Preferably, the semiconductor substrate is a bulk substrate. In this case, the area of a junction between the source region and the body region is large as compared with a SOI substrate, and therefore, the effect of reducing the body current becomes large.

In the semiconductor layer except for the source region and the drain region, a junction portion bordering on a bottom of the source region or the drain region contains the impurity of the first conductivity type with a higher concentration than in the body region except for the junction portions bordering on the source region and the drain region. With this structure, an energy barrier is provided at a portion in which the area of a junction between the body region and the source region and drain region is large. Therefore, the body current is effectively reduced.

The semiconductor layer includes a SiGe layer formed of Si₁₋ₓGeₓ (0<x≦1) on or above the body region. With this structure, for example, in a p-channel transistor, it is possible to confine carriers within the SiGe layer. Further, since the mobility of SiGe is larger than that of silicon, a field effect transistor with a reduced threshold voltage and higher performance can be realized.

The semiconductor layer includes: a Si buffer layer provided on the body region; the SiGe layer provided on the Si buffer layer; and a Si cap layer provided on the SiGe layer and under the gate dielectric film. With this structure, the carriers can be confined within the SiGe layer more efficiently. In addition, the mobility is further improved because the carriers can pass through a region of excellent crystallinity.

Preferably, the region at the junction portion bordering on the source region or the drain region which contains the impurity of the first conductivity type with a higher concentration than in the body region except for the junction portions bordering on the source region and the drain region has a thickness equal to or greater than 10 nm and equal to or smaller than 80 nm. When a region containing an impurity with a high concentration has a thickness smaller than 10 nm, this region would not function as an energy barrier against the body current. If the region has a thickness greater than 80 nm, this is substantially the same as a structure containing the impurity introduced throughout the entire body region. As a result, the mobility is deteriorated.

The semiconductor layer includes a silicon carbon layer formed of Si₁₋ₓCₓ (0<x<1) on or above the body region. With this structure, carriers can be confined within the silicon carbon layer by utilizing a difference in the band structure from silicon. Thus, the mobility can be improved.

The semiconductor layer includes a silicon germanium carbon layer formed of Si_{1-x-y}GeₓC_{y} (0<x<1, 0<y<1, 0<x+y<1) on or above the body region. With this structure, carriers can be confined within the silicon germanium carbon layer by utilizing a difference in the band structure from silicon irrespective of the conductivity type of the transistor. Thus, the mobility can be improved.

A complementary field effect transistor of the present invention comprises: a first field effect transistor which includes a first semiconductor layer provided on a semiconductor substrate, the first semiconductor layer including a first body region that contains an impurity of a first conductivity type, a first gate dielectric film provided on the first semiconductor layer, a first gate electrode provided on the first gate dielectric film, the first gate electrode and the first body region being electrically short-circuited, and a first source region and a first drain region provided in the first semiconductor layer at positions below the sides of the first gate electrode, the first source region and the first drain region containing an impurity of a second conductivity type; and a second field effect transistor which includes a second semiconductor layer provided on a semiconductor substrate, the second semiconductor layer including a second body region that contains an impurity of the second conductivity type, a second gate dielectric film provided on the second semiconductor layer, a second gate electrode provided on the second gate dielectric film, the second gate electrode and the second body region being electrically short-circuited, and a second source region and a second drain region provided in the second semiconductor layer at positions below the sides of the second gate electrode, the second source region and the second drain region containing an impurity of the first conductivity type, wherein in the first semiconductor layer except for the first source region and the first drain region, at least part of a junction portion bordering on the first source region or the first drain region contains the impurity of the first conductivity type with a higher concentration than in the first body region except for junction portions bordering on the first source region and the first drain region, and in the second semiconductor layer except for the second source region and the second drain region, at least part of a junction portion bordering on the second source region or the second drain region contains the impurity of the second conductivity type with a higher concentration than in the second body region except for junction portions bordering on the second source region and the second drain region.

With this structure, the power consumption is reduced in both the first field effect transistor and the second field effect transistor as compared with a conventional field effect transistor. Thus, the power consumption can also be effectively reduced in an entire CMOS circuit, for example.

A fabrication method of the present invention for fabricating a field effect transistor which includes a semiconductor layer provided on a semiconductor substrate, the semiconductor layer including a first body region that contains an impurity of a first conductivity type, a gate dielectric film provided on the semiconductor layer, a gate electrode provided on the gate dielectric film, the gate electrode and the body region being electrically short-circuited, and a source region and a drain region provided in the semiconductor layer at positions below the sides of the gate electrode, the source region and the drain region containing an impurity of a second conductivity type, the method comprising the steps of: (a) implanting an impurity of a first conductivity type in the semiconductor layer to form a first impurity region that contains the impurity of the first conductivity type with a higher concentration in a junction region of the semiconductor layer which borders on a bottom of at least one of the source region and the drain region than in the body region except for a junction region which borders on the source region and the drain region; (b) implanting an impurity of a second conductivity type in the semiconductor layer to form the source region and the drain region; and (c) implanting an impurity of a first conductivity type in the semiconductor layer to form a second impurity region that contains the impurity of the first conductivity type with a higher concentration in a junction region of the semiconductor layer which borders on a side surface of at least one of the source region and the drain region than in the body region except for a junction region which borders on the source region and the drain region.

With the above method, in the semiconductor layer except for the source region and the drain region, a junction portion bordering on the source region or the drain region contains the impurity of the first conductivity type with a higher concentration than in the body region except for junction portions bordering on the source region and the drain region.

The fabrication method further comprises, prior to steps (b) and (c), step (d) of forming the gate electrode above the semiconductor layer, wherein at steps (b) and (c) a common resist mask is used, and ion implantation is performed using the gate electrode as a mask. With this method, a region containing the impurity of the first conductivity type with a high concentration can be formed using a self-aligned method. Thus, the number of masks can be reduced, and the production cost can also be reduced.

### BRIEF DESCRIPTION OF DRAWINGS

FIG. 1(a) is a cross-sectional view showing a structure of a DTMOS according to embodiment 1 of the present invention. FIG. 1(b) is a plan view showing the p-channel DTMOS.

FIG. 2 is an energy band chart where negative gate voltage Vg is applied to the DTMOS of embodiment 1.

FIG. 3 illustrates the gate voltage dependency of the drain current and body current in the DTMOS of embodiment 1.

FIG. 4 illustrates the change of the transconductance-gate voltage characteristic of the DTMOS according to the body concentration.

FIG. 5 is a cross-sectional view showing a structure of a complementary DTMOS according to embodiment 2 of the present invention.

FIG. 6 is an energy band chart where positive gate voltage Vg is applied to the DTMOS of embodiment 2.

FIG. 7 illustrates the relationship between the drain current and body current and the gate voltage in the complementary DTMOS of embodiment 2.

FIG. 8 shows an example of a circuit which uses the complementary DTMOS of embodiment 2.

FIG. 9 is a cross-sectional view showing a structure of a complementary DTMOS according to embodiment 3 of the present invention.

FIG. 10 is a cross-sectional view illustrating the body current in the DTMOS where a SiGe layer is used as a channel.

FIG. 11 illustrates the first fabrication method of the complementary DTMOS of embodiment 2 of the present invention.

FIG. 12 illustrates the first fabrication method of the complementary DTMOS of embodiment 2.

FIG. 13(a) illustrates the first fabrication method of the complementary DTMOS of embodiment 2. FIG. 13(b) illustrates the second fabrication method of the complementary DTMOS of embodiment 2.

FIG. 14 is an enlarged view illustrating a fabrication method of the complementary DTMOS of embodiment 2.

FIG. 15 is an enlarged view illustrating a fabrication method of the complementary DTMOS of embodiment 2.

FIG. 16 is an enlarged view illustrating a fabrication method of the complementary DTMOS of embodiment 2.

FIG. 17 is an enlarged view illustrating a fabrication method of the complementary DTMOS of embodiment 2.

FIG. 18 is a cross-sectional view showing a conventional DTMOS.

FIG. 19 illustrates the drain current-gate voltage characteristic for illustrating the operation principle of the DTMOS.

FIG. 20 is a characteristic graph which illustrates the relationship between the drain current and body current and the gate voltage in the conventional DTMOS.

### BEST MODE FOR CARRYING OUT THE INVENTION

### Embodiment 1

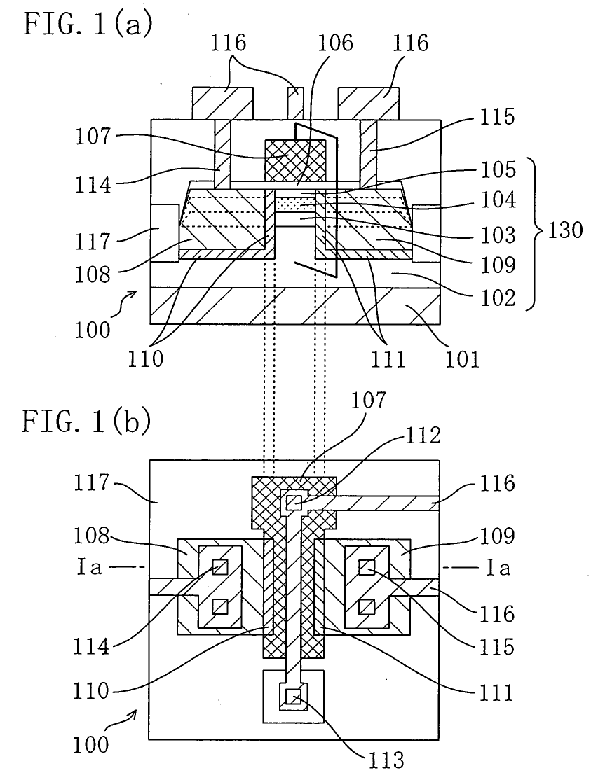

A field effect transistor according to embodiment 1 of the present invention is described with reference to FIGS. 1 to 4. FIG. 1(a) is a cross-sectional view of a p-channel dynamic threshold MOSFET (DTMOS) 100 which uses silicon germanium (SiGe). FIG. 1(b) is a plan view showing the DTMOS. The cross section shown in FIG. 1(a) is taken along line Ia-Ia of FIG. 1(b).

As shown in FIGS. 1(a) and 1(b), the DTMOS 100 of embodiment 1 includes a bulk p⁻ silicon (Si) substrate 101, a semiconductor layer 130 provided on the p⁻ Si substrate 101, a gate dielectric film 106 formed of, for example, a silicon oxide film, on the semiconductor layer 130, a gate electrode 107 formed of p⁺ polysilicon on the gate dielectric film 106, and a source region 108 and a drain region 109 in the semiconductor layer 130 in regions below the sides of the gate electrode 107.

The semiconductor layer 130 is provided on the p⁻ Si substrate 101 and includes a body region 102 containing an n-type impurity, a Si buffer layer 103 provided on the body region 102, a SiGe layer 104 provided on the Si buffer layer 103, a Si cap layer 105 provided on the SiGe layer 104 and below the gate dielectric film 106, and the above-described source region 108 and drain region 109 which are in contact with the body region 102. The concentration of the impurity contained in the p⁻ Si substrate 101 is 1×10¹⁵ cm⁻³. The concentration of the n-type impurity contained in the body region 102 is 1×10¹⁸ cm⁻³. The concentration of the p-type impurity contained in the source region 108 and drain region 109 is about 2×10²⁰ cm⁻³. It should be noted that a region which is in contact with the source region 108 and drain region 109 may include a LDD region containing a p-type impurity of lower concentration than that of the source region 108 and drain region 109.

The Si buffer layer 103, the SiGe layer 104 and the Si cap layer 105 are each formed by crystal growth. These crystal-growth layers are formed by selective crystal growth only on a transistor formation region (active region) separated by an element separation oxide film 117. The Ge content ratio of the SiGe layer 104 is 20%. The thicknesses of the Si buffer layer 103, the SiGe layer 104, and the Si cap layer 105 are 10 nm, 15 nm, and 5 nm, respectively. These layers are not intentionally doped with any impurity. The thickness of the gate dielectric film 106 is 5 nm. The gate length and gate width of the gate dielectric film 106 are 0.5 μm and 10 μm, respectively. The gate electrode 107 and the body region 102 are electrically short-circuited to form a dynamic threshold MOSFET (DTMOS).

Other features of the DTMOS 100 of embodiment 1 than the above structure are now described. In the body region 102, the Si buffer layer 103, the SiGe layer 104 and the Si cap layer 105, a region 110 which is in the vicinity of a junction portion bordering on the source region 108 and a region 111 which is in the vicinity of a junction portion bordering on the drain region 109 contain an n-type impurity with a higher concentration than in the body region except for the vicinity of junction portions bordering on the source region 108 and the drain region 109. The concentrations of the n-type impurity in the region 110 and the region 111 are about 5×10¹⁸ cm⁻³ and about 2×10¹⁸ cm⁻³ respectively.

The thickness of the region 110 and the region 111 (value measured from each pn junction position) is 80 nm but may be preferably in the range from 10 nm to 80 nm. This feature will be described later in detail.

In the DTMOS 100 of embodiment 1, the source region 108 and the drain region are connected to lines 116 made of aluminum, or the like, through a source contact 114 and a drain contact 115, respectively. The gate electrode 107 and the body region 102 are connected to the lines 116 through a gate contact 112 and a body contact 113, respectively.

In the DTMOS 100 of embodiment 1, when no voltage is applied to the gate electrode 107, no drain current flows between the source region 108 and the drain region 109 (off state). However, as a voltage is applied to the gate electrode 107 in a negative direction and the applied voltage is increased, the drain current is increased. At a certain threshold voltage or higher, the drain current is prominent, and the DTMOS 100 falls into a conductive state (on state).

Next, the characteristics of the DTMOS 100 of embodiment 1 are described.

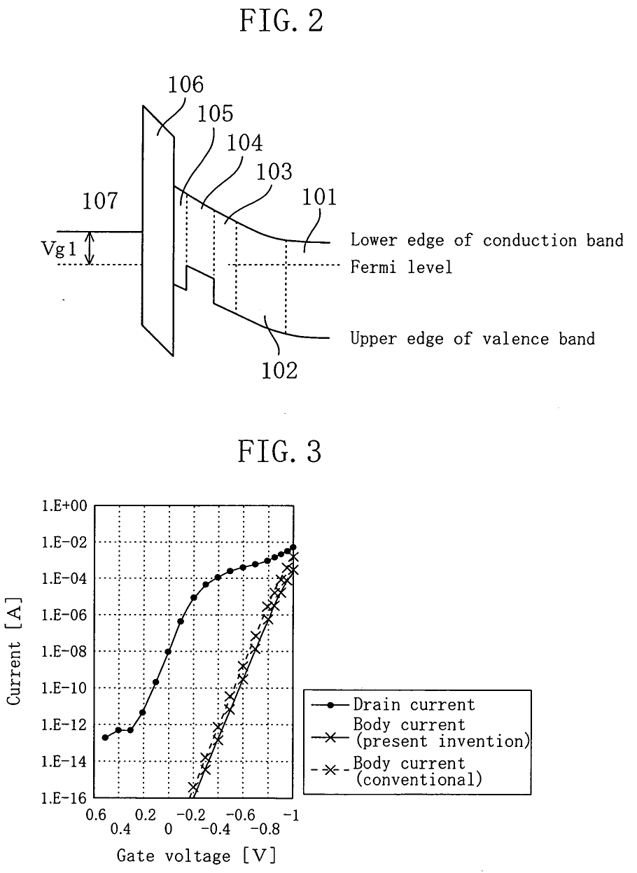

FIG. 2 is an energy band chart where negative gate voltage (i.e., body voltage) Vg is applied to the p-channel DTMOS of embodiment 1.

As seen from FIG. 2, in the semiconductor layer 130 (see FIG. 1), the SiGe layer 104 has a high potential at the edges of its valence band as compared with the Si cap layer 105 and the Si buffer layer 103. That is, the SiGe layer 104 has low energy at the edges of its valence band with respect to holes as compared with the Si cap layer 105 and the Si buffer layer 103. Therefore, holes are more likely to occur in the SiGe layer 104 than in the Si cap layer 105 and the Si buffer layer 103. Thus, the DTMOS of embodiment 1 can be turned on with a lower driving voltage as compared with a DTMOS which is entirely formed of Si. Accordingly, the threshold voltage can be decreased. As described above, in the DTMOS of embodiment 1, a channel is mainly formed in the SiGe layer 104. Since the SiGe layer 104 is formed on Si which-has a different lattice constant, the lattice of the SiGe layer 104 has a slight strain. Thus, the DTMOS of embodiment 1 also has advantages that high mobility is realized as compared with normal Si and that a large driving current can be generated.

Since the gate electrode 107 and the body region 102 are electrically short-circuited, the body voltage increases as the gate voltage increases. Since the body region 102 and the source region 108 and drain region 109 constitute pn junction diodes, a forward direction voltage is applied to these diodes as the body voltage increases, and accordingly, the body current increases. Electric current Ib which flows through the pn junction diode is expressed by Expression (1):
Ib=qA((De/Le)(ni²/NA)+(Dh/Lh)(ni²/ND))(exp(qVf/kT)−1) (1)
where q is the charge amount of electrons, A is the area of the pn junction, De and Dh are the diffusion coefficients of electrons and holes, respectively, Le and Lh are the diffusion lengths of electrons and holes, respectively, ni is the intrinsic carrier concentration, NA is the acceptor concentration in p-type semiconductor in the vicinity of a junction portion bordering on the n-type semiconductor, ND is the donor concentration in n-type semiconductor in the vicinity of a junction portion bordering on the p-type semiconductor, Vf is the forward direction voltage applied to the pn junction, k is the Boltzmann constant, and T is the absolute temperature.

As seen from the above expression, the electric current flowing through the pn junction diode, i.e., body current Ib, exponentially increases as forward direction voltage Vf increases. It is further seen that body current Ib increases as impurity concentrations NA and ND decrease (body current Ib is inversely proportional to impurity concentrations NA and ND) and that body current Ib is substantially determined by the smaller one of impurity concentrations NA and ND. In the case of DTMOS, the impurity concentration of the body region 102 is far smaller than those of the source region 108 and drain region 109, and accordingly, the body current is substantially determined by the impurity concentration of the body region 102. Therefore, body current Ib can be suppressed by increasing the impurity concentration of the body region 102.

In the case of MOSFET, a method called “pocket injection” is used for locally controlling the impurity concentration in the body region 102 in the vicinities of the source region and drain region. This method is used for suppressing a short channel effect while suppressing deterioration of carrier mobility and an increase in threshold voltage. A feature of this pocket injection is a so-called retrograde profile wherein the profile in the depth direction is such that the impurity concentration in a shallow region in the vicinity of the gate dielectric film is small, and the impurity concentration gradually increases as the depth increases.

Although the regions 110 and 111 of the DTMOS of embodiment 1 shown in FIGS. 1(a) and 1(b) may be formed using the same method as the pocket injection, the performance of the regions 110 and 111 can be improved by forming the regions 110 and 111 using other methods. Specifically, in the DTMOS of embodiment 1, the effect of suppressing the body current does not depend on the depth direction profile. For example, the same effect can also be achieved when the regions 110 and 111 are formed at a relatively shallow position in the vicinity of the gate dielectric film, and the impurity concentration is increased to be higher than in the other body regions. It is estimated that the increase in impurity concentration slightly deteriorates the mobility. However, in the DTMOS, an effect unique to the DTMOS, e.g., the capability of increasing the transconductance by increasing the impurity concentration as described later, can be attained. Thus, improvement in performance of the device as a whole can be expected.

Although the p-type source region 108 is connected to the ground, the p-type drain region 109 is connected to the negative power supply. Therefore, the body-drain junction is biased in the reverse direction, and a component of the body current which flows from the body region 102 to the source region 108 becomes dominant. Thus, increasing the impurity concentration of the body region 102 in the vicinity of the junction portion bordering on the source region 108 produces a more outstanding effect on suppression of the body current. In the DTMOS of embodiment 1, based on the above concept, the concentration of the n-type impurity contained in the junction portion between the source region 108 and the body region 102 (region 110) is higher than that of the n-type impurity contained in the junction portion between the drain region 109 and the body region 102 (region 111). With this feature, the impurity concentration in the region 111 can be decreased while the body current is effectively suppressed. Therefore, deterioration in the carrier mobility is suppressed, and an increase in parasitic capacitance is also suppressed.

As expressed in expression (1), the body current Ib is proportional to area A of the pn junction. Therefore, in the DTMOS of the present invention, when a bulk substrate which has a large area pn junction as compared with a SOI substrate is used, the body current is strongly suppressed. Further, the area of the junction portion at the bottom of the source region 108 and drain region 109 occupies a large part of the entire junction portion. Thus, when, at the junction between the body region 102 and the source region 108 or drain region 109, part of the body region 102 which is at the bottom of the source region 108 or drain region 109 has a higher impurity concentration, the body current is effectively suppressed. Since an electric current flowing between the side wall of the source region 108 and the body region 102 occupies a large part of the body current, the body current is effectively suppressed when the impurity concentration of the body region 102 at the junction portion bordering on the side surface of the source region 108 or drain region 109 is higher. Herein, the side surface of the source region means a portion of the source region which faces the drain region. As well, the side surface of the drain region means a portion of the drain region which faces the source region.

FIG. 3 illustrates the dependency of the drain current and body current on the gate voltage in the DTMOS of embodiment 1. With a definition of the threshold voltage “a drain current of 50 nA flows when the ratio of the gate width and the gate length of the gate electrode (gate width/gate length) is 1”, the ratio of “gate width/gate length” is 20 in the DTMOS of embodiment 1. Thus, the threshold voltage is about −0.1 V, with which a drain current of 1 μA flows.

FIG. 3 shows two body currents, where the solid line indicates the body current in the DTMOS of embodiment 1, and the broken line indicates the body current in a conventional DTMOS. Herein, the conventional DTMOS, which is used for comparison as to the body current, is an element wherein the impurity concentration of the body region 102 is constant (1×10¹⁸ cm⁻³) even in a region in the vicinity of the pn junction.

As shown in FIG. 3, in the DTMOS of embodiment 1, in the body region 102, the concentration of n-type impurity is higher in the region 110 which is in the vicinity of the junction portion bordering on the source region 108 and in the region 111 which is in the vicinity of the junction portion bordering on the drain region 109 than in the other part of the body region 102, whereby the body current is suppressed to about a ⅕. This is also seen from expression (1). It should be noted that the drain current is substantially equal between the DTMOS of embodiment 1 and the conventional DTMOS as shown in FIG. 3. Thus, in the DTMOS of embodiment 1, the body current can be reduced without changing the drain current.

Further, as shown in FIG. 3, in the DTMOS of embodiment 1, under a high gate voltage, the body current is nonnegligible as compared with the drain current. Thus, the power consumption of the entire DTMOS can be suppressed by decreasing the body current. Therefore, the DTMOS of embodiment 1 is extremely beneficial for practical use. For example, the DTMOS of embodiment 1 enables a longer life of battery for portable devices, such as mobile phones, or the like.

Further, the impurity concentration of a region in the vicinity of a junction portion bordering on the source region 108 and drain region 109 is higher than in the other part of the body region 102, whereby the spread of a depletion layer in the body region 102 is suppressed, and the short channel effect is also suppressed. Thus, the DTMOS of embodiment 1 is extremely beneficial for practical use.

As shown in FIG. 1, in the DTMOS of embodiment 1, in the n-type body region 102, the concentration of n-type impurity is high in the regions 110 and 111 which are in the vicinity of the junction portions bordering on the p-type source region 108 and drain region 109. In general, the performance of the DTMOS is improved by increasing the impurity concentration in the body region 102 as described below.

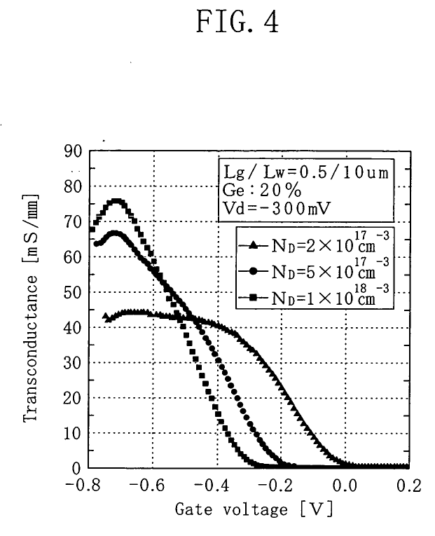

FIG. 4 illustrates the change of the transconductance-gate voltage characteristic of the DTMOS according to the impurity concentration in the body region 102 (body concentration; ND). In the measurement shown in FIG. 4, the drain voltage is −300 mV. As seen from the result shown in FIG. 4, the peak value of the transconductance increases as the body concentration increases. This is because the above-described substrate bias effect increases as the body concentration increases, i.e., because the change of the threshold voltage of the MOSFET according to the change of the body voltage becomes large (see FIG. 17). Further, it is seen that the threshold voltage increases toward the negative voltage side as the body concentration increases.

As described above, although the increase in concentration of the body region 102 results in an increase in transconductance, the threshold voltage increases on the other hand, and reduction in the supply voltage becomes difficult. However, in the DTMOS of embodiment 1, the impurity concentration is high not entirely in the body region 102 but only in the vicinity of the junction portions between the body region 102 and the source region 108 and drain region 109. Thus, the body current can be greatly decreased while the entire body concentration is set such that a high transconductance is secured, and the impurity concentration is increased only in the vicinity of the junction portion so as to suppress the increase of the threshold voltage. In the DTMOS of embodiment 1, the n-type impurity may be contained with a high concentration not only in the body region 102 but also in the vicinity of the junction portion between the Si buffer layer 103, SiGe layer 104 and Si cap layer 105 and the source region 108 and drain region 109. However, the regions 110 and 111 which contain n-type impurity with a high concentration are confined in the vicinity of the junction portion bordering on the source region 108 and drain region 109, and therefore, high transconductance can be secured.

In the DTMOS of embodiment 1, the thickness of the regions 110 and 111 is preferably equal to or greater than 10 nm and equal to or smaller than 80 nm, although it slightly varies according to the gate length. This is because when the thickness of the regions 110 and 111 is smaller than 10 nm, the regions 110 and 111 are unlikely to function as energy barriers against the body current. When the thickness of the regions 110 and 111 is greater than 80 nm, the distribution of impurity in the entire body region becomes substantially uniform.

The concentration of n-type impurity contained in the region 110 is preferably equal to or higher than 2×10¹⁸ cm⁻³ and equal to or lower than 1×10¹⁹ cm⁻³.

It should be noted that, although the DTMOS of embodiment 1 shown in FIG. 1 has the region 110 and the region 111, the DTMOS of embodiment 1 may have only the region 110 because in the body current a component which flows from the body region 102 to the source region 108 is dominant. Alternatively, the region 110 may be provided only in a part of the junction portion between the body region 102 and the source region. As a result, the transconductance is improved as compared with the DTMOS shown in FIG. 1.

In the DTMOS of embodiment 1, the channel layer is formed of Si₁₋ₓGeₓ (0<x≦1). However, Si, strained Si, silicon germanium carbon (Si_{1-x-y}GeₓC_{y}) (0<x<1, 0<y<1, 0<x+y<1) and silicon carbon (Si₁₋ₓCₓ) (0<x<1) may be used as the material of the channel layer.

In embodiment 1, the p-channel DTMOS has been described. However, in the case of an n-channel DTMOS, the same effects as those of the p-channel DTMOS of embodiment 1 can be obtained by introducing a p-type impurity in a body region with a higher concentration in junction portions bordering on a source region and a drain region.

A device which has a different device structure from that of the DTMOS of embodiment 1, for example, a vertical type field effect transistor, a field effect transistor on a SOI substrate, or the like, can achieve the same effects as those of the DTMOS of embodiment 1.

Although the DTMOS has been described in the above embodiment, the essence of the present invention is such that the impurity concentration in the vicinity of a pn junction is partially increased so as to suppress a diode current. The same effect can be obtained even when the present invention is applied to a semiconductor device other than DTMOS.

### Embodiment 2

A complementary field effect transistor according to embodiment 2 of the present invention is described with reference to the drawings.

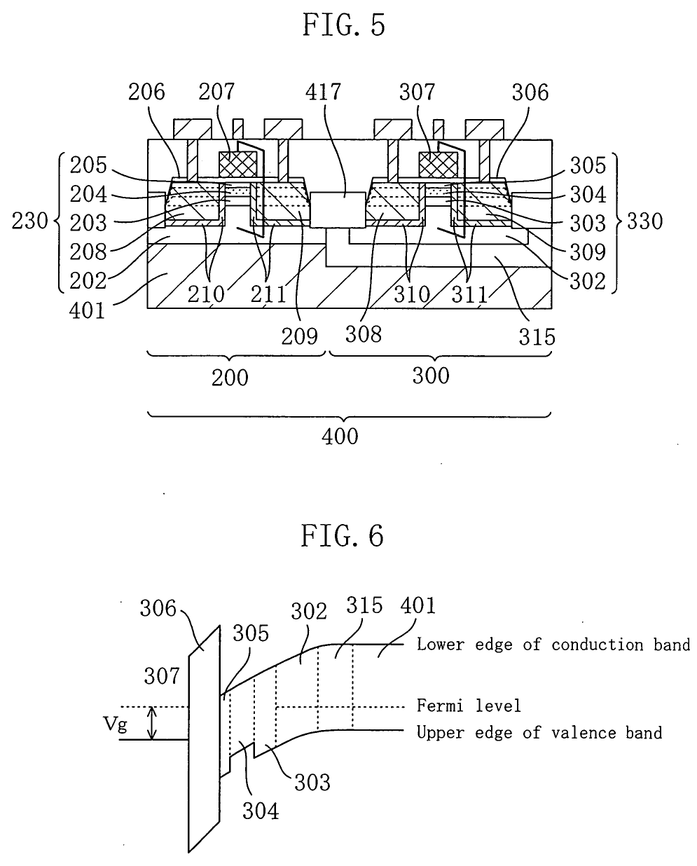

FIG. 5 is a cross-sectional view of a CMOS (complementary) dynamic threshold MOSFET (DTMOS) 400 which uses silicon germanium (SiGe). The complementary DTMOS 400 shown in FIG. 5 includes a bulk p⁻ silicon (Si) substrate 401 and a p-channel DTMOS 200 and n-channel DTMOS 300 which are formed on the substrate 401. The impurity concentration in the p-type Si substrate 401 is 1×10¹⁵ cm⁻³.

As described hereinabove, in the DTMOS, the body region and the gate electrode are short-circuited, and a voltage applied to the body region varies according to the gate voltage, i.e., a signal. Thus, the body region has to be separately formed in each device. Therefore, when a complementary DTMOS is formed on a bulk substrate, the well structure is a triple well structure as shown in FIG. 5. The structure of the p-channel DTMOS 200 and n-channel DTMOS 300 is the same as that of the first DTMOS.

Specifically, the complementary DTMOS 400 of embodiment 2 includes a p-type Si substrate 401, an n-type well 315 including a first transistor formation region which is provided on the p-type Si substrate 401, a p-type body region (p-type well) 302 provided on the n⁻ well 315, n-type body region (n-type well) 202 including a second transistor formation region which is provided on the p-type Si substrate 401, and a device-separating dielectric film 417 for separating the first transistor formation region and the second transistor formation region.

The p-channel DTMOS 200 of the complementary DTMOS 400 includes a first semiconductor layer 230 provided on the first transistor formation region of the n-type body region 202, a first gate dielectric film 206 provided on the first semiconductor layer 230, a first gate electrode 207 formed of p⁺ polysilicon on the first gate dielectric film 206, and a source region 208 and drain region 209 which are formed in parts of the first semiconductor layer 230 under regions at the sides of the first gate electrode 207 and both of which contain a p-type impurity.

The first semiconductor layer 230 further includes a first Si buffer layer 203, a first SiGe layer 204 provided on the first Si buffer layer 203, and a first Si cap layer 205 provided over the first SiGe layer 204 and under the first gate dielectric film 206. The first Si buffer layer 203, the first SiGe layer 204, and the first Si cap layer 205 are formed by crystal growth only in the first transistor formation region. The thicknesses of the first Si buffer layer 203, the first SiGe layer 204, and the first Si cap layer 205 are 10 nm, 15 nm, and 5 nm, respectively, and these layers are not intentionally doped. The Ge content ratio of the first SiGe layer 204 is 30%.

In the p-channel DTMOS 200 of embodiment 2, among the n-type body region 202, the first Si buffer layer 203, the first SiGe layer 204 and the first Si cap layer 205, a region 210 in the vicinity of a junction portion bordering on the source region 208 and a region 211 in the vicinity of a junction portion bordering on the drain region 209 have a high n-type impurity concentration as compared with the other region except for the junction portion of the n-type body region 202. The n-type impurity concentrations in the region 210 and the region 211 are 5×10¹⁸ cm⁻³ and 2×10¹⁸ cm⁻³, respectively. The thickness of the regions 210 and 211 (value measured from the pn junction position) is 80 nm.

On the other hand, the n-channel DTMOS 300 includes a second semiconductor layer 330 provided on the second transistor formation region of the p-type body region 302, a second gate dielectric film 306 provided on the second semiconductor layer 330, a second gate electrode 307 formed of n⁺ polysilicon on the second gate dielectric film 306, and a source region 308 and drain region 309 which are formed in parts of the second semiconductor layer 330 under regions at the sides of the second gate electrode 307 and both of which contain an n-type impurity.

The second semiconductor layer 330 further includes a second Si buffer layer 303, a second SiGe layer 304 provided on the second Si buffer layer 303, and a second Si cap layer 305 provided over the second SiGe layer 304 and under the second gate dielectric film 306. The second Si buffer layer 303, the second SiGe layer 304, and the second Si cap layer 305 are formed by crystal growth only in the second transistor formation region. The thicknesses of the second Si buffer layer 303, the second SiGe layer 304, and the second Si cap layer 305 are 10 nm, 15 nm, and 5 nm, respectively, and these layers are not intentionally doped. The Ge content ratio of the second SiGe layer 304 is the same as that of the first SiGe layer 204, i.e., 30%.

In the n-channel DTMOS of embodiment 2, among the p-type body region 302, the second Si buffer layer 303, the second SiGe layer 304 and the second Si cap layer 305, a region 310 in the vicinity of a junction portion bordering on the source region 308 and a region 311 in the vicinity of a junction portion bordering on the drain region 309 have a high p-type impurity concentration as compared with the other region except for the junction portion of the p-type body region. The p-type impurity concentrations in the region 310 and the region 311 are 3×10¹⁸ cm⁻³ and 1×10¹⁸ cm⁻³, respectively. The thickness of the regions 310 and 311 (value measured from the pn junction position) is 80 nm.

In the complementary DTMOS 400 of embodiment 2, the n-type body region 202 contains an impurity with a concentration of 1×10¹⁸ cm⁻³ the p-type body region 302 contains an impurity with a concentration of 5×10¹⁷ cm⁻³, and the n⁻ well 315 contains an impurity with a concentration of 1×10¹⁷ cm⁻³.

Both the first gate dielectric film 206 and the second gate dielectric film 306 have a thickness of 6 nm. Both the p-channel DTMOS 200 and the n-channel DTMOS 300 have a dual gate structure. The gate length and the gate width of the p-channel DTMOS 200 are 0.5 μm and 10 μm, respectively. The gate length and the gate width of the n-channel DTMOS 300 are 0.5 μm and 5 μm, respectively. Since the gate width of the p-channel DTMOS 200 is wider than that of the n-channel DTMOS 300, the both DTMOSs have an equal current driving capacity.

The concentration of an impurity contained in the source regions 208 and 308 and the drain regions 209 and 309 is 2×10²⁰ cm⁻³. It should be noted that, although not shown, the drain region 209 and the drain region 309 are connected to each other through contacts and a wire, and the first gate electrode 207 and the second gate electrode 307 are connected to each other through contacts and a wire.

FIG. 6 is an energy band chart where positive gate voltage (i.e., body voltage) Vg is applied to the n-channel DTMOS 300 of embodiment 2. As shown, a band discontinuity hardly occurs at a conduction band edge of the second SiGe layer 304 of the second semiconductor layer 330. Therefore, in the case of an n-channel DTMOS, a channel is formed on a surface of the second Si cap layer 305 as in a device formed only of Si.

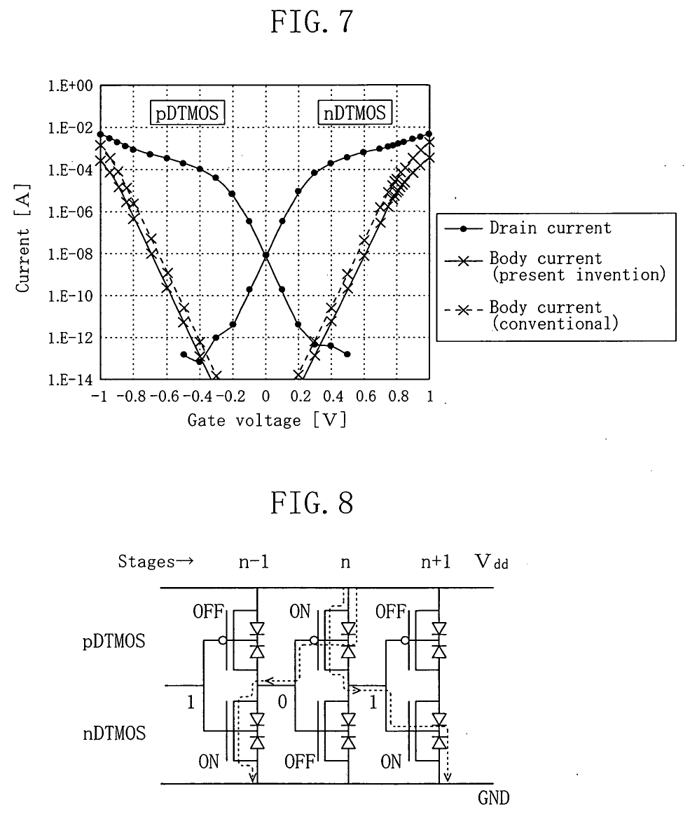

FIG. 7 illustrates the gate voltage dependency of the drain current and body current in the p-channel DTMOS and n-channel DTMOS of embodiment 2. With the definition described in embodiment 1, the threshold voltage is about −0.1 V in the p-channel DTMOS and is about 0.1 V in the n-channel DTMOS. In FIG. 7, the solid lines indicate the body currents in the n-channel DTMOS and p-channel DTMOS of embodiment 2, and the broken lines indicate the body currents of a conventional DTMOS for comparison wherein the impurity concentration in the body region is uniform even in the vicinity of pn junction. As seen from FIG. 7, in the body region, the impurity concentration is higher in a region in the vicinity of a junction portion bordering on the source region and in a region in the vicinity of a junction portion bordering on the drain region than in the other part of the body region, whereby the body current is suppressed in any of the p-channel device and the n-channel device. (It should be noted that the vertical axis is a logarithmic axis).

As shown in FIG. 7, under a high gate voltage (i.e., in a state where the gate voltage has a large absolute value), the body current is nonnegligible as compared with the drain current. Thus, the power consumption of the entire CMOS-type DTMOS can be suppressed by decreasing the body current. Therefore, the complementary DTMOS of embodiment 2 is extremely beneficial for practical use. For example, the complementary DTMOS of embodiment 2 enables a longer life of battery for portable devices, such as mobile phones, or the like.

Further, the impurity concentration of a region in the vicinity of junction portions bordering on the source region and drain region is higher than in the other part of the body region, whereby the spread of a depletion layer in the body region is suppressed, and the short channel effect is also suppressed.

FIG. 8 is a circuit diagram showing a circuit wherein inverters are multistage-connected, which is an example of a circuit using the complementary DTMOS of embodiment 2. In the exemplary circuit shown in FIG. 8, the inputs of inverters at stage “n−1” and stage “n+1” are 1 (output is 0), and the logical state of an inverter at stage “n” is inverse. FIG. 8 also shows the ON/OFF state of each DTMOS in the shown condition.

In the shown condition, in the circuit shown in FIG. 8, in a source-drain channel of a DTMOS in the ON state at a certain stage and a DTMOS in the OFF state at a subsequent stage, there is a static current leak path through a diode formed between body and source as illustrated by the broken lines. As a result, static power consumption of the inverter increases.

However, when the complementary DTMOS of embodiment 2 is used, a diode current flowing between body and source is sufficiently suppressed as described above. Thus, the increase of the static power consumption is suppressed to a minimum level, and the power consumption of the entire circuit is greatly reduced.

Although embodiment 2 has been described with an example of complementary DTMOS, the same effects can be achieved with a non-complementary device, e.g., a semiconductor device wherein a p-channel DTMOS and an n-channel DTMOS are formed on the same substrate.

In the DTMOS of embodiment 2, the specifications of the first semiconductor layer 230 and the second semiconductor layer 330, e.g., materials, thickness, etc., are not limited to those described above, but the same effects can be achieved with different specifications. Further, the parameters, such as the impurity concentrations in the respective layers, the device size, etc., are not limited to those described in embodiment 2. Generation of a body current can be suppressed so long as part of a body region at a junction portion bordering on a source region or drain region at least contains an impurity of the same conductivity type as that contained in the other part of the body region with a higher concentration than the other part of the body region does.

Also in the DTMOS of embodiment 2, a layer of silicon carbon (Si₁₋ₓCₓ, 0<x<1) or silicon germanium carbon (Si_{1-x-y}GeₓC_{y}, 0<x<1, 0<y<1, 0<x+y<1) may be used in substitution for the SiGe layer as in the DTMOS of embodiment 1. The composition of such a layer is optimized such that band discontinuity is produced at a junction portion, whereby electrons or holes are confined. As a result, the same effects as those obtained in a DTMOS which uses SiGe, for example, reduction of the threshold voltage, etc., are achieved, and the effects of the present invention are equivalently achieved.

### Embodiment 3

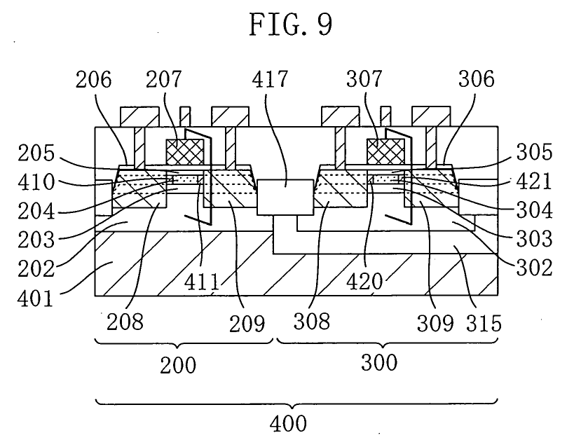

FIG. 9 is a cross-sectional view showing a structure of a complementary DTMOS according to embodiment 3 of the present invention. The complementary DTMOS of embodiment 3 is the same as the complementary DTMOS of embodiment 2 except for the positions of the regions 210, 211, 310 and 311. Therefore, the differences of the complementary DTMOS of embodiment 3 from the complementary DTMOS of embodiment 2 are only described. It should be noted that, in FIG. 9, the same elements as those of FIG. 5 are denoted by the same reference numerals used in FIG. 5.

In the p-channel DTMOS 200 of embodiment 3, the concentration of an n-type impurity contained in a junction portion bordering on the source region 208 and drain region 209 in the first SiGe layer 204 which functions as a channel is higher than that of an n-type impurity contained in the n-type body region 202 except for a junction portion bordering on the source region 208 and drain region 209. Specifically, in the first SiGe layer 204, the concentration of the n-type impurity contained in a region 410 at a junction portion bordering on the source region 208 is 5×10¹⁸ cm⁻³. In the first SiGe layer 204, the concentration of the n-type impurity contained in a region 411 at a junction portion bordering on the drain region 209 is 2×10¹⁸ cm⁻³. The width (thickness) of the regions 410 and 411 is equal to or greater than 10 nm and equal to or smaller than 80 nm.

In the n-channel DTMOS 300 of embodiment 3, the concentration of a p-type impurity contained in a junction portion bordering on the source region 308 and drain region 309 in the second SiGe layer 304 is higher than that of a p-type impurity contained in the p-type body region 302 except for a junction portion bordering on the source region 308 and drain region 309.

As described below, in the case of a DTMOS including a SiGe layer, a current flowing between the body region and the source region constitutes large part of the body current. Therefore, an impurity of a high concentration is introduced into a portion of the body region at a junction portion bordering on the source region to provide an energy barrier, whereby the body current is effectively reduced.

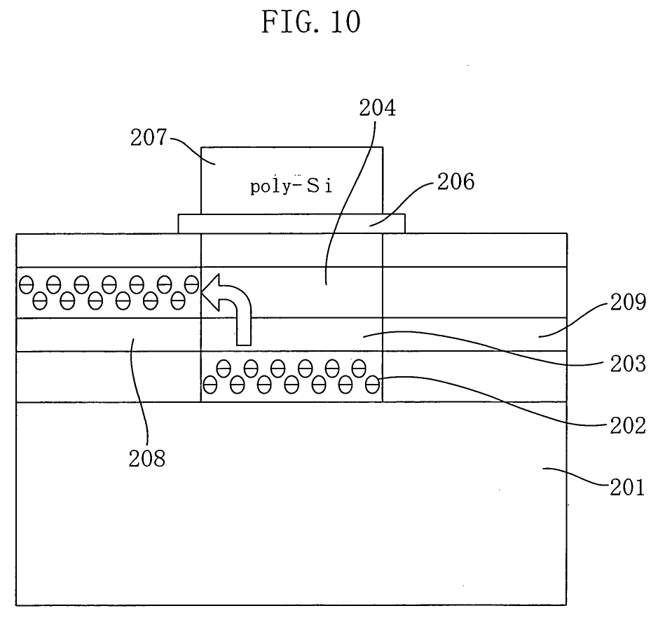

FIG. 10 is a cross-sectional view illustrating the body current in the p-channel DTMOS where a SiGe layer is used as a channel. In the DTMOS shown in FIG. 10, the regions 210 and 211 are not provided, although the same elements as those of the DTMOS of embodiment 2 are denoted by the same reference numerals.

In the p-channel DTMOS including a SiGe layer as a channel, when a voltage is applied between the source region 208 and the drain region 209, a first diode D1 is produced between the source region 208 and the first SiGe layer 204, and a second diode D2 is produced between the source region 208 and the n-type body region 202.

In this case, the reverse saturation current density per unit area of the first diode D1 (Js1) is:

$$Js 1 = q \{ √ ( Dh / τ p ) \} ( {n}_{i - SiGe}^{2} / Nd - ) + q \{ √ ( De / τ n ) \} ( {n}_{i - SiGe}^{2} / Na ) , \qquad ( 2 )$$

where q is the charge amount of electrons, Dh is the diffusion coefficient of holes, De is the diffusion coefficient of electrons, τp is the lifetime of holes, τn is the lifetime of electrons, n_{i-SiGe} is the intrinsic carrier density of the first SiGe layer 204, Nd− is the donor concentration of the first SiGe layer 204, and Na is the acceptor concentration of the source region 208 and drain region 209.

At the right side of expression (2), the first term represents a current of holes, and the second term represents a current of electrons.

The hole current flowing through the first diode D1, which is represented by the first term of the right side of expression (2), flows in the drain region 209 without substantially flowing in the n-type body region 202 that contains n-type impurity and therefore does not contribute to the substrate current. The electron current flowing through the first diode D1, which is represented by the second term of the right side of expression (2), also flows in the n-type body region 202. Since the intrinsic carrier density in the SiGe layer, n_{i-SiGe}, is considerably large as compared with a Si layer, the electron current is nonnegligible.

The reverse saturation current density per unit area of the second diode D2 (Js2) is:

$$Js 2 = q \{ √ ( Dh / τ p ) \} ( {n}_{i - Si}^{2} / Nd + ) + q \{ √ ( De / τ n ) \} ( {n}_{i - Si}^{2} / Na ) , \qquad ( 3 )$$

where Nd+ is the donor concentration of the n-type body region, and Na is the acceptor concentration of the source region and drain region. At the right side of expression (3), the first term represents a current of holes, and the second term represents a current of electrons.

Since Na>Nd+, the hole current which is represented by the first term of the right side of expression (3) is dominant. However, Nd+ is increased by increasing the impurity concentration of the n-type body region 202, whereby the hole current can be controlled. In the DTMOS of embodiment 3, the impurity concentration in the n-type body region 202 except for a junction portion bordering on the source region 208 is 1×10¹⁸ cm⁻³. Therefore, the hole current of the second diode D2 is suppressed to a small size.

The electron current, which is represented by the second term of the right side of expression (3), also flows in the n-type body region 202. However, the electron current is negligibly small because the intrinsic carrier density in the Si layer, n_{i-Si}, is small and the acceptor concentration of the source region and drain region is high.

Because of the above, in the DTMOS including a SiGe layer as a channel, the electron current in expression (2) cannot be suppressed. Therefore, it is difficult to suppress the entire substrate current (Js1+Js2) to a small size.

Considering from a different viewpoint, since the impurity concentration in the source region 209 is set as high as 2×10²⁰ cm⁻³, the Fermi level is uniform among the first Si cap, the first SiGe layer, and the n-type body region. As a result, a pseudo potential well is produced on the conduction band side. Since the Si body and the SiGe channel are both n-type layers and the Si body contains n-type impurity with a higher concentration, electrons readily flow from the Si body to the SiGe channel. Since in the SiGe film the SiGe channel is an n-type region of low concentration and the source is a p-type region of high concentration, a PN junction is formed therebetween to provide the first diode D1. Therefore, there is a possibility that a forward direction voltage from the Si body to the body-source region causes electrons to flow from the Si body to the SiGe channel, and these electrons are removed by the source.

In the DTMOS of embodiment 3, the concentration of n-type impurity contained in the first SiGe layer 204 in the vicinity of a junction portion bordering on the source region 208 is higher than in the other part of the first SiGe layer 204. Therefore, an electron current flowing between the source region 208 and the first SiGe layer 204, which is dominant in the body current, can be suppressed. Thus, in the DTMOS of embodiment 3, the power consumption can be reduced without deteriorating the characteristics, such as the channel mobility, etc.

### Embodiment 4

As embodiment 4 of the present invention, the first method for fabricating the complementary DTMOS of embodiment 2 is described.

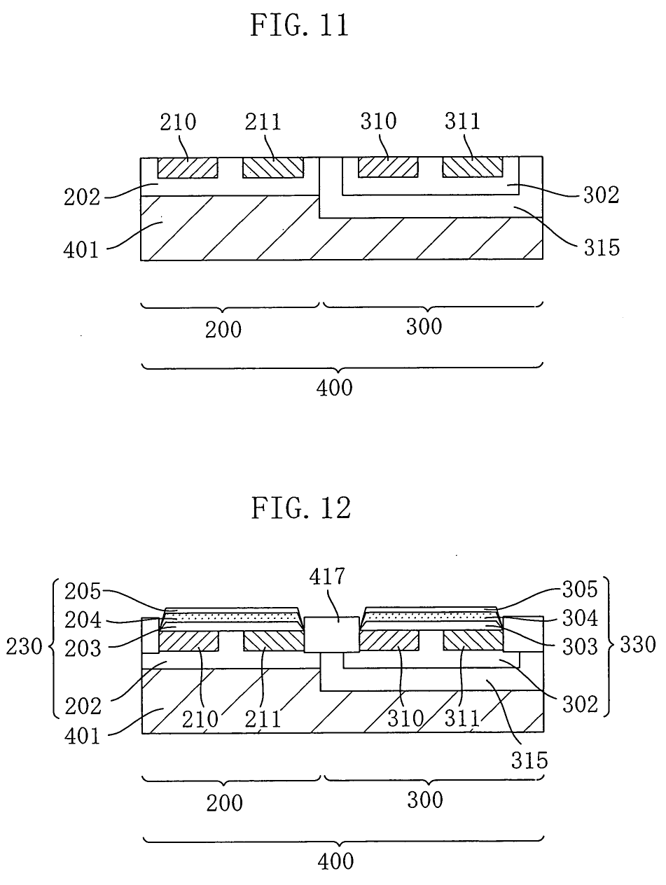

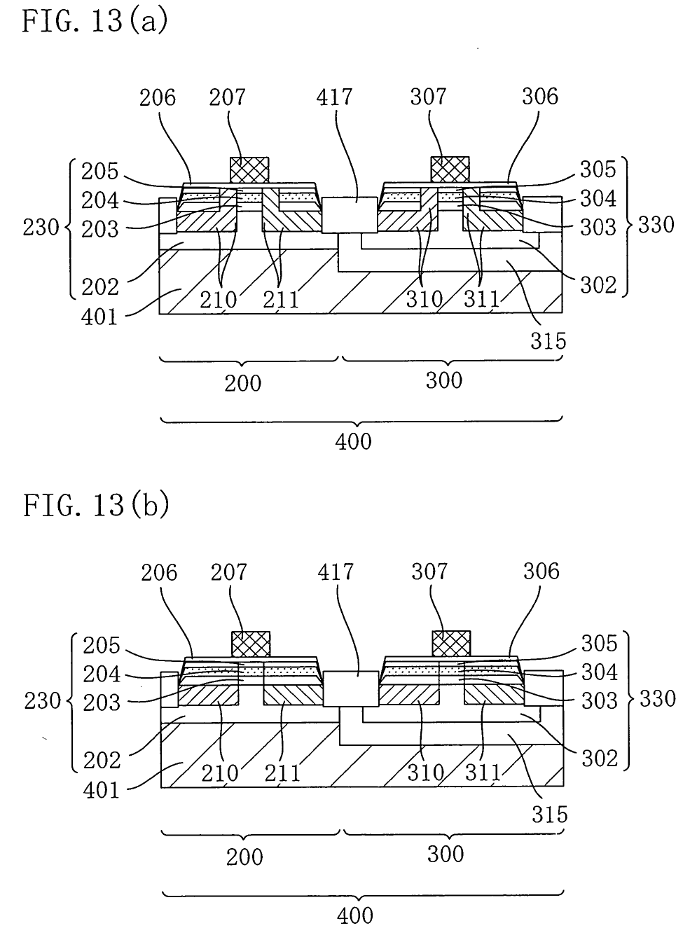

FIG. 11, FIG. 12 and FIG. 13 are cross-sectional views showing a fabrication method of a CMOS-type (complementary) dynamic threshold MOSFET (DTMOS) formed using silicon germanium (SiGe) according to embodiment 4.

Firstly, as shown in FIG. 11, a bulk p⁻ Si substrate 401 containing an impurity with a concentration of 1×10¹⁵ is prepared, and trivalent phosphorus (P³⁺) are ion-implanted in a desired region of the p⁻ Si substrate 401 using a mask formed by lithography, whereby an n⁻ well 315 is formed for an n-channel DTMOS. This ion implantation process is carried out with an implantation energy of 540 KeV and a dose of 5×10² cm⁻².

Then, phosphorus ions are implanted in a desired region of the p⁻ Si substrate 401, whereby an n-type body region 202 is formed for a p-channel DTMOS. In this ion implantation process, divalent phosphorus (P²⁺) is first implanted with an implantation energy of 280 keV and a dose of 3.5×10¹³ cm⁻², and then, monovalent phosphorus (P⁺) is implanted with an implantation energy of 90 keV and a dose of 2×10¹³ cm⁻².

Then, a p-type body region 302 for the n-channel DTMOS is formed in a desired region on the n⁻ well 315. In this ion implantation process, boron ions (B⁺) are first implanted with an implantation energy of 150 keV and a dose of 1.5×10¹³ cm⁻², and then, boron ions (B⁺) are implanted with an implantation energy of 30 keV and a dose of 1.5×10¹³ cm⁻².

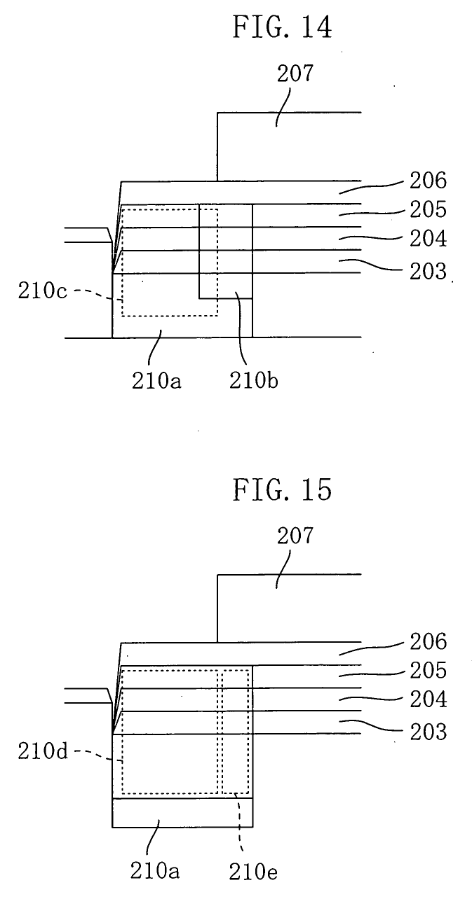

Then, additional implantation is performed for partially increasing the impurity concentration of the n-type body region 202 and p-type body region 302. In this implantation process, for the p-channel DTMOS, arsenic ions (As⁺) are implanted into the n-type body region 202 with an implantation energy of 40 keV and a dose of 1×10¹⁴ cm⁻², whereby a region 210a (see FIG. 14) which will be a junction portion bordering on the bottom of a source region is formed. Subsequently, arsenic ions (As⁺) are implanted into the n-type body region 202 with an implantation energy of 40 keV and a dose of 4×10¹³ cm⁻², whereby a region 211a which will be a junction portion bordering on the bottom of a drain region is formed. Thereafter, for the n-channel DTMOS, BF₂ ions are implanted into the p-type body region 302 with an implantation energy of 30 keV and a dose of 1×10³ cm⁻², whereby a region 310a which will be a junction portion bordering on the bottom of a source region is formed. Subsequently, BF₂ ions are implanted into the p-type body region 302 with an implantation energy of 30 keV and a dose of 2×10¹³ cm⁻², whereby a region 311a which will be a junction portion bordering on the bottom of a drain region is formed. In this example, the region 310a which will be a junction portion bordering on the source region and the region 311a which will be a junction portion bordering on the drain region have different doses but may have the same dose for performing implantation at one time and accordingly simplifying the fabrication process. In the case of fabricating the DTMOS of embodiment 3, the ion implantation process may be omitted. After the implantation, a thermal treatment is performed in a nitrogen atmosphere at 950° C. for 0 minutes such that the impurities are activated.

Then, as shown in FIG. 12, an oxide film is buried in a device separation region on the substrate 401 using a well-known shallow trench formation technique to determine a transistor formation region. The depth of the trench is 400 nm. Thereafter, the resultant substrate is washed, and then, on an active region of the substrate, a Si layer having a thickness of 10 nm, a SiGe layer having a thickness of 15 nm (Ge content ratio: 30%), and a Si layer having a thickness of 15 nm are subsequently grown by UHW-CVD, whereby a first Si buffer layer 203, a first SiGe layer 204 and a first Si cap layer 205 are formed on the n-type body region 202, and a second buffer layer 303, a second SiGe layer 304 and a second Si cap layer 305 are formed on the p-type body region 302. At this step, optimum crystal growth conditions are selected such that Si and SiGe are selectively grown only in a transistor formation region (active region) in which the substrate is exposed. The source gases used for Si and Ge are Si₂H₆ (disilane) and GeH₄ (germane), respectively. During growth of Si, the flow rate of Si₂H₆ is 20 mL/min, the growth temperature is 600° C., and the growth rate is about 8 nm/min. During growth of SiGe (Ge content: 30%), the flow rates of Si₂H₆ and GeH₄ are 20 mL/min and 60 mL/min, respectively. The growth temperature is 600° C. as is the case with Si. The growth rate is 60 nm/min. To improve the selectivity of growth, it is desirable to slightly add Cl₂ gas. Throughout the growth of the Si and SiGe layers, doping is not intentionally carried out.

Then, the first Si cap layer 205 and the second Si cap layer 305 are subjected to thermal oxidation, whereby a first gate dielectric film 206 and a second gate dielectric film 306 are formed as shown in FIG. 13(a). At this step, the oxidation temperature is 750° C., and the thickness of each gate oxide film is 6 nm. At the washing and thermal oxidation steps prior to formation of the gate oxide film, the first Si cap layer 205 and the second Si cap layer 305 shrink by about 10 nm to finally have a thickness of about 5 nm.

Then, additional implantation is performed for partially increasing the impurity concentration of the n-type body region 202 and p-type body region 302. In this implantation process, for the p-channel DTMOS, arsenic ions (As⁺) are implanted into the n-type body region 202 with an implantation energy of 40 keV and a dose of 1×10¹⁴ cm⁻², whereby a region 210b (see FIG. 14) which will be a junction portion bordering on the source region is formed. Subsequently, arsenic ions (As⁺) are implanted into the n-type body region 202 with an implantation energy of 40 keV and a dose of 4×10¹³ cm⁻², whereby a region 211b which will be a junction portion bordering on the drain region is formed. Thereafter, for the n-channel DTMOS, BF₂ ions are implanted into the p-type body region 302 with an implantation energy of 30 keV and a dose of 1×10¹³ cm⁻², whereby a region 310b which will be a junction portion bordering on the source region is formed. Subsequently, BF₂ ions are implanted into the p-type body region 302 with an implantation energy of 30 keV and a dose of 2×10¹³ cm⁻², whereby a region 311b which will be a junction portion bordering on the drain region is formed. In this example, the region 310b which will be a junction portion bordering on the source region and the region 311b which will be a junction portion bordering on the drain region have different doses of implantation. However, a same dose of ions may be implanted in these regions at one time for the purpose of simplifying the fabrication process. At this step, the ion implantation angle and the implantation energy are appropriately selected, such that impurity of a high concentration is introduced into only part of the body region at a junction portion bordering on the source region or drain region as in the DTMOS of embodiment 3.

Then, a polycrystalline silicon film (undoped) is deposited over the substrate by LP-CVD so as to have a thickness of 200 nm. The deposition temperature is 600° C.

Then, to obtain a dual-structure gate electrode, a p-type impurity is ion-implanted in a p-channel DTMOS formation region, and an n-type impurity is ion-implanted in an n-channel DTMOS formation region. Thereafter, patterning is carried out by dry etching, and a first gate electrode 207 and a second gate electrode 307 of the dual structure are formed on the first gate dielectric film 206 and the second gate dielectric film 306, respectively. The gate length and the gate width are 0.5 μm and 10 μm, respectively, in the p-channel DTMOS, and 0.5 μm and 5 μm, respectively, in the n-channel DTMOS.

After the pattern formation by photolithography, BF₂ ions are implanted with an acceleration voltage of 30 keV and a dose of 4×10¹⁵ cm⁻², whereby a source region 208 and a drain region 209 of the p-channel DTMOS and a contact for the body of the n-channel DTMOS are formed. Then, As ions are implanted with an acceleration voltage of 40 keV and a dose of 4×10¹⁵ cm⁻², whereby a source region 308 and a drain region 309 of the n-channel DTMOS and a contact for the body of the p-channel DTMOS are formed. In these ion implantation steps, the first gate electrode 207 and the second gate electrode 307 are used as masks. As a result, among the aforementioned regions 210a, 210b, 211a, 211b, 310a, 310b, 311a and 311b, the conductivity type of the region in which the above-described high concentration implantation for source and drain regions has been performed (region 210c shown in FIG. 14) is inverted. After the implantation, for the purpose of activating the impurities, a thermal treatment is performed by RTA in a nitrogen atmosphere at 950° C. for 15 seconds. As a result, regions 210, 211, 310 and 311 are formed. It should be noted that the first gate electrode 207 does not exist immediately above the region 210c shown in FIG. 14.

Then, an interlayer dielectric film is formed on the resultant structure so as to have a thickness of 500 nm, and thereafter, a thermal treatment is performed to activate the ion-implanted impurity. Subsequently, a contact hole for wires is formed, and Al (aluminum) is deposited. Thereafter, electrodes and wire patterns are formed by dry etching. At the final step, the resultant structure is sintered in a hydrogen atmosphere, whereby the complementary DTMOS shown in FIG. 5 is completed.

In a DTMOS formed by the above-described fabrication method, the impurity concentration is not high throughout the entire body region but high only in the vicinity of the junction portions bordering on a source region and a drain region. Therefore, when the impurity concentration is high only in the vicinity of the junction portions while the impurity concentration of the entire body region is set such that high transconductance can be secured, the body current can be greatly reduced while suppressing the increase of the threshold voltage.

### Embodiment 5

As embodiment 5 of the present invention, the second method for fabricating the complementary DTMOS of the present invention is described. The second fabrication method is partially different from the first fabrication method described in embodiment 4. Therefore, only the differences from the first fabrication method are described. FIG. 14 to FIG. 17 are enlarged views showing the source region and the body region of a p-channel DTMOS for illustrating ion implantation.

The process lasting from formation of wells on a p-type Si substrate to device separation, crystal growth, and formation of a gate dielectric film is the same as that of the above-described first fabrication method as illustrated in FIG. 11 and FIG. 12.

In the second fabrication method, a gate electrode is formed prior to additional implantation that is performed for increasing the impurity concentration in the vicinity of a side wall junction between the body region and the source region and drain region, and thereafter, a high concentration region is formed by a self-aligned method.

Specifically, the first gate dielectric film 206 and the second gate dielectric film 306 are formed after the crystal growth step shown in FIG. 12. Thereafter, a polycrystalline silicon film (undoped) is deposited by LP-CVD over the substrate so as to have a thickness of 200 nm. The deposition temperature is 600° C.

Then, to obtain a dual-structure gate electrode, a p-type impurity is ion-implanted in a p-channel DTMOS formation region, and an n-type impurity is ion-implanted in an n-channel DTMOS formation region. Thereafter, patterning is carried out by dry etching, and a first gate electrode 207 and a second gate electrode 307 of the dual structure are formed. The gate length and the gate width are 0.5 μm and 10 μm, respectively, in the p-channel DTMOS, and 0.5 μm and 5 μm, respectively, in the n-channel DTMOS.

Then, in order to partially increase the impurity concentration of the n-type body region 202 and p-type body region 302, additional implantation is performed using a self-aligned method where the above-formed gate electrode is used as a mask. The mask used for forming the source and drain regions is also used for photoresist. For the p-channel DTMOS, arsenic ions (As⁺) are implanted with an implantation energy of 40 keV and a dose of 1×10¹⁴ cm⁻². For the n-channel DTMOS, BF₂ ions are implanted with an implantation energy of 30 keV and a dose of 1×10¹³ cm⁻². The impurity concentration of the above-described first gate electrode 207 and second gate electrode 307 is higher than the impurity concentration selected for increasing the concentration of the body region. Thus, the ion implantation in this step does not cause the conductivity type of the gate electrode to be inverted. As a result, a region 210d shown in FIG. 15 is doped with arsenic. As a matter of course, the regions 211, 310 and 311 are substantially the same as the case of FIG. 15. Hereinafter, regions corresponding to the region 210d are referred to as regions 211d, 310d and 311d. It should be noted that, in this case, the region 210e shown in FIG. 15 is not intentionally doped. It should be further noted that, in FIG. 15, the first gate electrode 207 does not exist immediately above the region 210a but immediately above the region 210e.

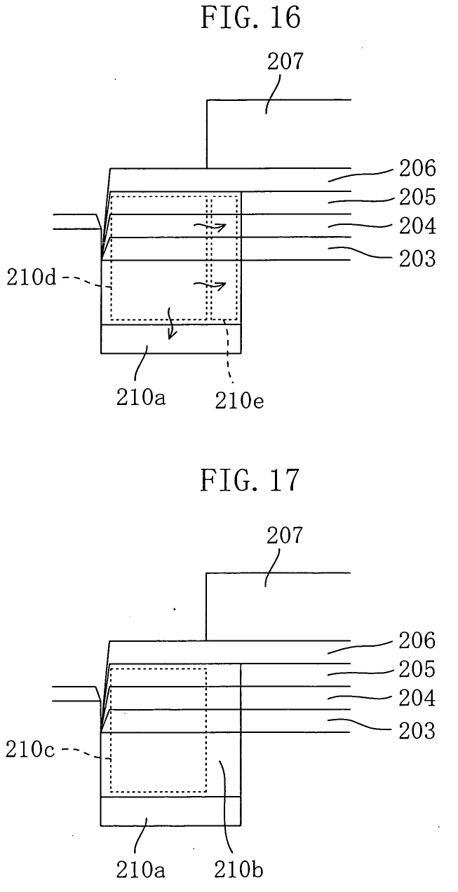

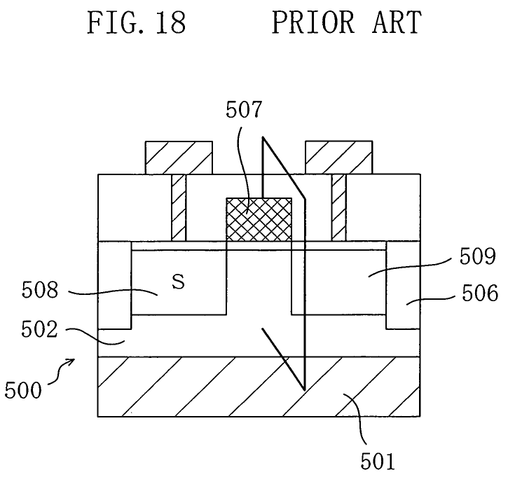

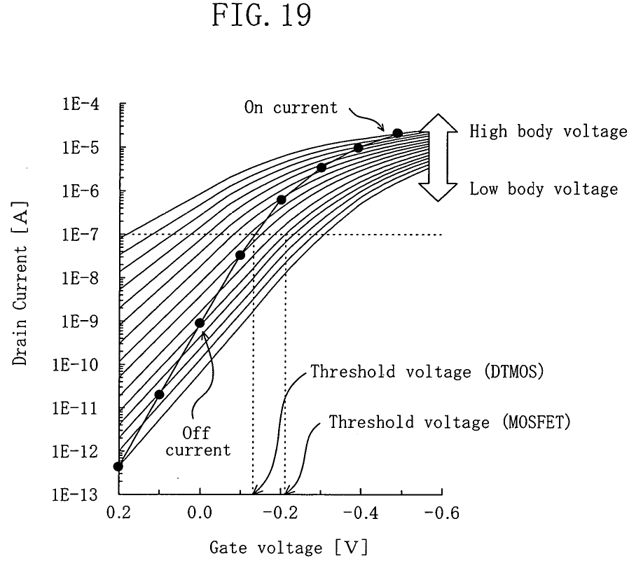

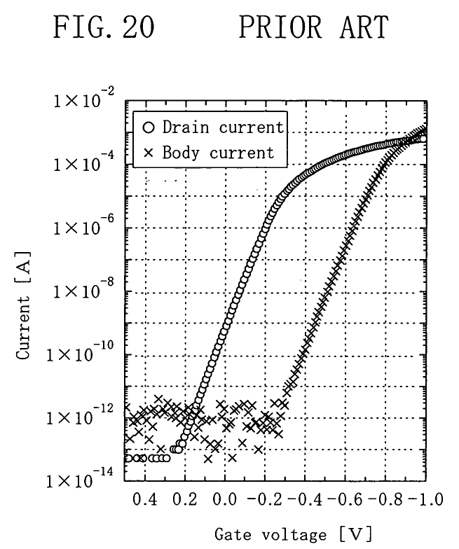

After the ion implantation, the first thermal treatment is performed in a nitrogen atmosphere at 950° C. for 0 minutes such that the impurity is diffused into a region under the gate electrode as shown in FIG. 16. At this step, the structure shown in FIG. 13(b) is completed. In FIG. 16, arrows extending from the region 210d to the region 210a and the region 210e represent diffusion of the impurity. Herein, the region 210a, the region 210b and the region 210e contain the impurity of the same conductivity type. As a matter of course, the same applies to the region 211, the region 310 and the region 311.

Then, after the pattern formation by photolithography using the mask used in the above-described additional implantation step, BF₂ ions are implanted into an area ranging from the upper part of the n-type body region 202 to the first Si buffer layer 203, the first SiGe layer 204 and the first Si cap layer 205 with an implantation energy of 30 keV and a dose of 4×10¹⁵ cm⁻² using the first gate electrode 207 as a mask, whereby a source region 208 and a drain region 209 of the p-channel DTMOS and a contact for the body of the n-channel DTMOS are formed.

Then, As ions are implanted with an acceleration voltage of 40 keV and a dose of 4×10¹⁵ cm⁻² using the second gate electrode 307 as a mask, whereby a source region 308 and a drain region 309 of the n-channel DTMOS and a contact for the body of the p-channel DTMOS are formed. As a result, among the regions 210, 211, 310 and 311, the conductivity type is inverted in an area in which the high concentration implantation has been performed for the source region and drain region (region 210c shown in FIG. 17). Also as for the regions 211, 310 and 311, the conductivity type is inverted in an area in which the impurity for the source region and the drain region has been implanted. (Hereinafter, regions corresponding to the region 210c are referred to as regions 211c, 310c and 311c).

After the above-described ion implantation, the second thermal treatment is performed by RTA in a nitrogen atmosphere at 950° C. for 15 seconds, whereby diffusion of the impurities is suppressed to a minimum degree. As a result, part of the regions 210, 211, 310 and 311, i.e., part of the body region in the vicinity of the junction portions bordering on the source region and drain region (the regions 210a and 210b in the region 210), remains as a high impurity concentration region.

Preferably, the relationship between the time of the first thermal treatment, t1, and the time of the second thermal treatment, t2, is t1>t2. This is because phosphorus diffuses when t2 is large.

Subsequent steps are the same as those of the first fabrication method, and at the end of the subsequent steps, the complementary DTMOS shown in FIG. 5 is completed. In the second fabrication method, it is not necessary to use an exclusive mask for formation of the regions 210, 211, 310 and 311 (side wall junction portions) which are the high impurity concentration junction regions. Therefore, the number of masks is reduced, and the cost reduction and process simplification are realized.

In a DTMOS formed by the above-described fabrication method, the impurity concentration is not high throughout the entire body region but high only in the vicinity of the junction portions bordering on a source region and a drain region. Therefore, the impurity concentration can be set high only in the vicinity of the junction portions while the impurity concentration of the entire body region is set such that high transconductance can be secured. As a result, the body current can be greatly reduced while suppressing the increase of the threshold voltage.

In the DTMOS fabrication method of embodiment 5, the second ion implantation step for forming the regions 210, 211, 310 and 311 in the side surfaces of the source region and drain region may be performed prior to the ion implantation step for forming the source region and drain region, and vice versa.

### INDUSTRIAL APPLICABILITY

A DTMOS of the present invention is preferably used for various electronic devices in which reduction in power consumption is a challenge to be addressed, such as mobile phones, and the like.

1-14. (canceled)

15. A field effect transistor, comprising:
a semiconductor substrate;
a semiconductor layer provided on the semiconductor substrate, the semiconductor layer including a body region which contains an impurity of a first conductivity type;
a gate dielectric film provided on the semiconductor layer;
a gate electrode provided on the gate dielectric film; and
a source region and a drain region provided in the semiconductor layer at positions below the sides of the gate electrode, the source region and the drain region containing an impurity of a second conductivity type,
wherein the gate electrode and the body region are electrically short-circuited, and
at least part of a junction portion between the source region and the body region contains the impurity of the first conductivity type with a higher concentration than in the junction portion between the drain region and the body region.

16. The field effect transistor of claim 15, wherein in the semiconductor layer except for the source region and the drain region, a junction portion bordering on a side surface of the source region contains the impurity of the first conductivity type with a higher concentration than in the body region except for the junction portion bordering on the source region.

17. The field effect transistor of claim 16, wherein:
the semiconductor layer includes a SiGe layer formed of Si₁₋ₓGeₓ (0<x≦1) on or above the body region; and
in the SiGe layer, a junction portion bordering on the source region contains the impurity of the first conductivity type with a higher concentration than in the body region except for the junction portion bordering on the source region.

18. The field effect transistor of claim 15, wherein the semiconductor substrate is a bulk substrate.

19. The field effect transistor of claim 15, wherein in the semiconductor layer except for the source region and the drain region, a junction portion bordering on a bottom of the source region contains the impurity of the first conductivity type with a higher concentration than in the body region except for the junction portion bordering on the source region.

20. The field effect transistor of claim 15, wherein the semiconductor layer includes a SiGe layer formed of Si₁₋ₓGeₓ (0<x≦1) on or above the body region.

21. The field effect transistor of claim 20, wherein the semiconductor layer includes: a Si buffer layer provided on the body region; the SiGe layer provided on the Si buffer layer; and a Si cap layer provided on the SiGe layer and under the gate dielectric film.

22. The field effect transistor of claim 15, wherein the region at the junction portion bordering on the source region which contains the impurity of the first conductivity type with a higher concentration than in the body region except for the junction portion bordering on the source region has a thickness equal to or greater than 10 nm and equal to or smaller than 80 nm.

23. The field effect transistor of claim 15, wherein the semiconductor layer includes a silicon carbon layer formed of Si₁₋ₓCₓ (0<x<1) on or above the body region.

24. The field effect transistor of claim 15, wherein the semiconductor layer includes a silicon germanium carbon layer formed of Si_{1-x-y}GeₓC_{y} (0<x<1, 0<y<1, 0<x+y<1) on or above the body region.

25. A complementary field effect transistor, comprising:
a first field effect transistor which includes a first semiconductor layer provided on a semiconductor substrate, the first semiconductor layer including a first body region that contains an impurity of a first conductivity type, a first gate dielectric film provided on the first semiconductor layer, a first gate electrode provided on the first gate dielectric film, the first gate electrode and the first body region being electrically short-circuited, and a first source region and a first drain region provided in the first semiconductor layer at positions below the sides of the first gate electrode, the first source region and the first drain region containing an impurity of a second conductivity type; and
a second field effect transistor which includes a second semiconductor layer provided on a semiconductor substrate, the second semiconductor layer including a second body region that contains an impurity of the second conductivity type, a second gate dielectric film provided on the second semiconductor layer, a second gate electrode provided on the second gate dielectric film, the second gate electrode and the second body region being electrically short-circuited, and a second source region and a second drain region provided in the second semiconductor layer at positions below the sides of the second gate electrode, the second source region and the second drain region containing an impurity of the first conductivity type,
wherein in the first semiconductor layer except for the first source region and the first drain region, at least part of a junction portion bordering on the first source region contains the impurity of the first conductivity type with a higher concentration than in the first body region except for a junction portion bordering on the first source region, and
in the second semiconductor layer except for the second source region, at least part of a junction portion bordering on the second source region contains the impurity of the second conductivity type with a higher concentration than in the second body region except for a junction portion bordering on the second source region.

26. A method for fabricating a field effect transistor which includes a semiconductor layer provided on a semiconductor substrate, the semiconductor layer including a first body region that contains an impurity of a first conductivity type, a gate dielectric film provided on the semiconductor layer, a gate electrode provided on the gate dielectric film, the gate electrode and the body region being electrically short-circuited, and a source region and a drain region provided in the semiconductor layer at positions below the sides of the gate electrode, the source region and the drain region containing an impurity of a second conductivity type, the method comprising the steps of:
(a) implanting an impurity of a first conductivity type in the semiconductor layer to form a first impurity region that contains the impurity of the first conductivity type with a higher concentration in a junction region of the semiconductor layer which borders on a bottom of the source region than in the body region except for a junction region which borders on the source region;
(b) implanting an impurity of a second conductivity type in the semiconductor layer to form the source region and the drain region; and
(c) implanting an impurity of a first conductivity type in the semiconductor layer to form a second impurity region that contains the impurity of the first conductivity type with a higher concentration in a junction region of the semiconductor layer which borders on a side surface of the source region than in the body region except for a junction region which borders on the source region.

27. The method of claim 26, further comprising, prior to steps (b) and (c), step (d) of forming the gate electrode above the semiconductor layer,
wherein at steps (b) and (c) a common resist mask is used, and ion implantation is performed using the gate electrode as a mask.

28. The field effect transistor of claim 15, wherein the junction portion between the drain region and the body region further contains the impurity of the first conductivity type with a lower concentration than in at least part of the junction portion between the source region and the body region.
